(19) United States
(12) Patent Application Publication
(10) Pub. No.: US 2006/0185581 A1
(43) Pub. Date: Aug. 24, 2006

(54) Method for producing a semiconductor wafer

(75) Inventors: Hiroji Aga, Gunma (JP); Nobuhiko Noto, Gunma (JP); Kiyoshi Mitani, Gunma (JP)

Correspondence Address: OLIFF & BERRIDGE, PLC, P.O. BOX 19928, ALEXANDRIA, VA, 22320, US

(73) Assignee: SHIN-ETSU HANDOTAI CO., LTD., TOKYO (JP)

(21) Appl. No.: 11/353,046

(22) Filed: Feb. 14, 2006

(30) Foreign Application Priority Data
Feb. 24, 2005 (JP) 2005-049170

(51) Int. Cl. C30B 23/00; C30B 25/00; C30B 28/12; C30B 28/14

(52) U.S. Cl. 117/89; 117/902

(57) ABSTRACT

The present invention provides a method for producing a semiconductor wafer comprising at least steps of, forming a Si_{1-X}Ge_{X} layer (0<X<1) with a critical film-thickness at a deposition temperature of the layer or thinner on a surface of a silicon single crystal wafer and then forming a Si layer with a critical film-thickness at a temperature of later relaxing heat-treatment or thinner thereon, forming an ion-implanted layer for relaxation inside the silicon single crystal wafer by implanting at least one kind of hydrogen ion, rare gas ion, and Si ion through the Si layer, thereafter performing the relaxing heat-treatment, thereby to make the Si_{1-X}Ge_{X} layer lattice-relaxed and to form a strained Si layer by introducing lattice strain in the Si layer, thereafter depositing Si on a surface of the strained Si layer, and thereby to increase a thickness of the strained Si layer. Thereby, there is provided a method for producing a semiconductor wafer formed with a strained Si layer in which misfit dislocation is not generated and the layer has sufficient strain and has a thickness which can apply to device designs of various specifics.

### BACKGROUND OF THE INVENTION

1. Field of the Invention

The present invention relates to a method for producing a semiconductor wafer in which a strained Si layer is formed, for example, on an insulator.

2. Description of the Related Art

In recent years, in order to meet demands for high-speed semiconductor devices, on a Si (silicon) single crystal wafer, a Si_{1-X}Ge_{X} layer (0<X<1, hereinafter occasionally described as a SiGe layer simply) and a Si layer are epitaxial-grown in order. There has been proposed semiconductor devices, such as a high-speed MOSFET (Metal-Oxide-Semiconductor Field Effect Transistor), in which the Si layer is used in a channel region.

In this case, because a Si_{1-X}Ge_{X} crystal is larger than a Si crystal in a lattice constant, tensile strain is caused in a Si crystal epitaxial-grown on a Si_{1-X}Ge_{X} layer (hereinafter, the Si layer in which strain is caused is referred to as a strained Si layer). An energy band structure of a Si crystal is changed by the strain stress. As a result, degeneracy of the energy band is dissolved and an energy band with high carrier-mobility is formed. Therefore, MOSFET in which the strained Si layer is used as a channel region has a high-speed operation property that is higher than usual at about 1.3-8 times.

As a method for forming such a strained Si layer, there has been proposed a method for producing a wafer comprising steps of, forming a thick Graded SiGe layer and a Si_{1-X}Ge_{X} layer with relaxed lattice strain on a surface of a silicon single crystal wafer (a bulk SiGe substrate), further forming a strained Si layer on the wafer so as to be a bond wafer, bonding the bond wafer to a base wafer, and producing a wafer having a SSOI (Strained Silicon On Insulator) structure by an ion implantation and delamination method (alternatively, referred to as Smart Cut (registered trademark) method) (See, for example, T. A. Langdo et al., Appl. Phys. Lett., vol. 82, p. 4256 (2003)). Here, a Graded SiGe layer is a layer formed so that lattice strain in the SiGe layer is relaxed by performing epitaxial growth with a Ge concentration in the SiGe layer increased at a constant and loose rate of change.

However, in the case that a SSOI wafer is produced by this method, the bulk SiGe substrate as described above requires a thick Graded SiGe layer having several micrometers, therefore throughput is bad and the substrate becomes very expensive.

On the other hand, as another method for forming the strained Si layer, there has been disclosed a method comprising steps of, forming a Si_{1-X}Ge_{X} layer with a critical film-thickness or thinner on a surface of a silicon single crystal wafer and then forming a Si layer with a desired thickness thereon, thereafter forming an ion-implanted layer to make the Si_{1-X}Ge_{X} layer lattice-relaxed in a surface layer of the silicon single crystal wafer by implanting hydrogen ions and such from a surface thereof, thereafter performing the relaxing heat-treatment, thereby to make the Si_{1-X}Ge_{X} layer lattice-relaxed and to form a strained Si layer by introducing lattice strain in the Si layer (See, for example, U.S. Pat. No. 6,464,780, Japanese Patent Application Laid-Open (kokai) No. 2003-7615, and No. 2003-234289). In this case, bubble, crack, crystal defect and such are formed in the ion-implanted layer. It has been thought that lattice relaxation is promoted by the presence of them. In addition, a critical film-thickness that misfit dislocation caused by difference of respective lattice constants is not generated at the interface between the silicon single crystal wafer and the Si_{1-X}Ge_{X} layer.

### SUMMARY OF THE INVENTION

The object of the present invention is to provide a method for producing a semiconductor wafer having a strained Si layer in which misfit dislocation is not generated and the layer has sufficient strain and has a thickness which can apply to device designs of various specifics.

For accomplishing the above object, the present invention provides a method for producing a semiconductor wafer comprising at least steps of, forming a Si_{1-X}Ge_{X} layer (0<X<1) with a critical film-thickness at a deposition temperature of the layer or thinner on a surface of a silicon single crystal wafer and then forming a Si layer with a critical film-thickness at a temperature of a later relaxing heat-treatment or thinner thereon, forming an ion-implanted layer for relaxation inside the silicon single crystal wafer by implanting at least one kind of hydrogen ion, rare gas ion, and Si ion through the Si layer, thereafter performing the relaxing heat-treatment, thereby to make the Si_{1-X}Ge_{X} layer lattice-relaxed and to form a strained Si layer by introducing lattice strain in the Si layer, thereafter depositing Si on a surface of the strained Si layer, and thereby to increase a thickness of the strained Si layer.

If a Si_{1-X}Ge_{X} layer with a critical film-thickness at a deposition temperature of the layer or thinner is formed on a surface of a silicon single crystal wafer and a Si layer with a critical film-thickness at a temperature of relaxing heat-treatment or thinner is formed thereon and an ion-implanted layer for relaxation is formed inside the silicon single crystal wafer by implanting at least one kind of hydrogen ion, rare gas ion, and Si ion through the Si layer and thereafter the relaxing heat-treatment is performed and thereby to make the Si_{1-X}Ge_{X} layer lattice-relaxed and to form a strained Si layer by introducing lattice strain in the Si layer as described above, misfit dislocation is not generated in the strained Si layer in the relaxing heat-treatment, generation of threading-dislocation can be suppressed, surface-roughness by generation of crosshatch can be suppressed, and a favorable strained Si layer can be formed. And thereafter, if Si is deposited on a surface of the strained Si layer and thereby to increase a thickness of the strained Si layer, dislocation or surface-roughness can be suppressed and there can be produced a semiconductor wafer formed with a strained Si layer that has sufficient strain corresponding to lattice relaxation of the Si_{1-X}Ge_{X} layer, and has a thickness which can apply to device designs of various specifics. In addition, a critical film-thickness of each of the Si layer and the Si_{1-X}Ge_{X} layer is a maximum film-thickness that misfit dislocation is not generated.

In this case, it is preferable that an ion-implanted layer for delamination is formed inside the silicon single crystal wafer by implanting at least one kind of hydrogen ion and rare gas ion through the strained Si layer with the increased thickness, a surface of the strained Si layer with the increased thickness of the silicon single crystal wafer as a bond wafer and a surface of a base wafer are closely bonded directly or through an insulator film, thereafter delamination is performed at the ion-implanted layer for delamination, and the strained Si layer with the increased thickness is exposed by removing the most surficial Si layer and the Si_{1-X}Ge_{X} layer transferred to the side of the base wafer by the delamination.

If an ion-implanted layer for delamination is formed inside the silicon single crystal wafer by implanting at least one kind of hydrogen ion and rare gas ion through the strained Si layer with the increased thickness and a surface of the strained Si layer with the increased thickness of the silicon single crystal wafer as a bond wafer and a surface of a base wafer are closely bonded directly or through an insulator film, this has a sufficient thickness for device production, and there is no surface-roughness by crosshatch in the strained Si layer and therefore void defects are not generated when they are bonded. And thereafter, if delamination is performed at the ion-implanted layer for delamination and the strained Si layer with the increased thickness is exposed by removing the most surficial Si layer and the Si_{1-X}Ge_{X} layer transferred to the side of the base wafer by the delamination, dislocation and surface-roughness are prevented, there can be produced a semiconductor wafer having a SSOI structure formed with the strained Si layer that has sufficient strain and has a thickness which can apply to device designs of various specifics.

Moreover, the present invention provides a method for producing a semiconductor wafer comprising at least steps of, forming a Si_{1-X}Ge_{X} layer (0<X<1) with a critical film-thickness at a deposition temperature of the layer or thinner on a surface of a silicon single crystal wafer and then forming a Si layer with a critical film-thickness at a temperature of a later relaxing heat-treatment or thinner thereon, forming an ion-implanted layer for relaxation inside the silicon single crystal wafer by implanting at least one kind of hydrogen ion, rare gas ion, and Si ion through the Si layer, thereafter performing the relaxing heat-treatment, thereby to make the Si_{1-X}Ge_{X} layer lattice-relaxed and to form a strained Si layer by introducing lattice strain in the Si layer, thereafter forming an ion-implanted layer for delamination inside the silicon single crystal wafer by implanting at least one kind of hydrogen ion and rare gas ion through the strained Si layer, closely bonding a surface of the strained Si layer of the silicon single crystal wafer as a bond wafer and a surface of a base wafer directly or through an insulator film, thereafter performing delamination at the ion-implanted layer for delamination, exposing the strained Si layer by removing the most surficial Si layer and the Si_{1-X}Ge_{X} layer transferred to the side of the base wafer by the delamination, and thereafter depositing Si on a surface of the strained Si layer, and thereby to increase a thickness of the strained Si layer.

Also, in the case that after a strained Si layer having no misfit dislocation is formed by formation of an ion-implanted layer for relaxation and relaxing heat-treatment, each of steps such as forming a ion-implanted layer for delamination, bonding of wafers, delaminating, and exposing the strained Si layer is performed and thereafter a step of depositing Si to increase a thickness of the strained Si layer is performed as described above, void defects are not generated even when they are bonded, dislocation and surface-roughness are prevented, and there can be produced a semiconductor wafer having a SSOI structure formed with the strained Si layer that has sufficient strain and has a thickness which can apply to device designs of various specifics.

Moreover, it is preferable that the step of depositing Si on a surface of the strained Si layer is performed at 800° C. or less.

Because the critical film-thickness in which misfit dislocation is not generated is larger as the temperature is lower, if the step of depositing Si on a surface of the strained Si layer is performed at 800° C. or less, particularly 650° C. or less, misfit dislocation is not generated in the strained Si layer newly, moreover strain having been induced in the strained Si layer is maintained, and the strained Si layer can be surely increased in a film-thickness to have a desired thickness.

Moreover, it is preferable that the Si_{1-X}Ge_{X} layer has X≧0.1.

If the Si_{1-X}Ge_{X} layer has X≧0.1 as described above, lattice strain can be sufficiently introduced to the Si layer. In particular, it is more preferable that the layer has X≧0.2.

Moreover, it is preferable that the thickness of the Si layer with the critical film-thickness or thinner to be formed is from 3 nm to 10 nm.

If the thickness of the Si layer with the critical film-thickness or thinner to be formed is from 3 nm to 10 nm as described above, misfit dislocation can be surely prevented from being generated in relaxing heat-treatment, and the thickness can become so sufficient that the layer is not feared to be perfectly removed by etching action in cleaning.

Moreover, it is preferable that the removing of the most surficial Si layer and/or the Si_{1-X}Ge_{X} layer is performed by at least any one of polishing, etching, and removing an oxide film after thermal oxidation at the temperature of 800° C. or less under an oxidizing atmosphere.

According to these methods, the most surficial Si layer and the Si_{1-X}Ge_{X} layer can be completely removed, and a strained Si layer having a flat and smooth surface can be exposed.

Moreover, it is preferable that a silicon single crystal wafer or an insulator wafer is used as the base wafer.

If the base wafer is a silicon single crystal wafer as described above, an insulator film can be easily formed by thermal oxidation, vapor growth method, or the like, the wafer can be closely bonded to a surface of the strained Si layer through the insulator film. Moreover, for the purpose of use, there may be used an insulator base wafer such as quartz, silicon carbide, alumina, and diamond.

Moreover it is preferable that the temperature of the relaxing heat-treatment is 900° C. or less.

If the temperature of the relaxing heat-treatment is 90° C. or less as described above, diffusion of Ge from the Si_{1-X}Ge_{X} layer can be suppressed, the strained Si layer can have large strain.

According to the present invention, if a Si_{1-X}Ge_{X} layer with a critical film-thickness at a deposition temperature of the layer or thinner is formed on a surface of a silicon single crystal wafer and then a Si layer with a critical film-thickness at a temperature of later relaxing heat-treatment or thinner is formed thereon and an ion-implanted layer for relaxation is formed inside the silicon single crystal wafer by implanting hydrogen ion and such through the Si layer and thereafter the relaxing heat-treatment is performed and thereby to make the Si_{1-X}Ge_{X} layer lattice-relaxed and to form a strained Si layer by introducing lattice strain in the Si layer as described above, misfit dislocation is not generated in the strained Si layer in the relaxing heat-treatment, generation of threading-dislocation can be suppressed, surface-roughness by generation of crosshatch can be suppressed, and a favorable strained Si layer can be formed. And thereafter, if Si is deposited on a surface of the strained Si layer and thereby to increase a thickness of the strained Si layer, dislocation and surface-roughness can be suppressed and there can be produced a semiconductor wafer having a strained Si layer that has sufficient strain corresponding to lattice relaxation of the Si_{1-X}Ge_{X} layer and has a thickness which can apply to device designs of various specifics.

### BRIEF EXPLANATION OF THE DRAWINGS

FIG. 1 is a flow chart showing an example of steps for producing a semiconductor wafer according to the present invention.

### DETAILED DESCRIPTION OF THE PREFERRED EMBODIMENTS

Hereinafter, the present invention will be described in detail. As described above, conventionally, there is a method comprising steps of, forming a Si_{1-X}Ge_{X} layer with a critical film-thickness or thinner on a surface of a silicon single crystal wafer and then forming a Si layer with a desired thickness thereon, thereafter forming an ion-implanted layer for relaxation in a surface layer of the silicon single crystal wafer by implanting hydrogen ions and such from a surface thereof, thereafter performing the relaxing heat-treatment, thereby to make the Si_{1-X}Ge_{X} layer lattice-relaxed and to form a strained Si layer by introducing lattice strain in the Si layer.

The present inventors thought to solve a problem that the thickness of the strained Si layer formed by this conventional method is limited to the critical film-thickness determined by a Ge concentration X of the Si_{1-X}Ge_{X} layer and temperatures (a deposition temperature of the Si layer or a heat-treatment temperature after the deposition) or thinner and there is no degree of freedom in device designs. Namely, if relaxing heat-treatment and such is performed after making the Si layer have a thickness required for device production, generation of misfit dislocation and such are generated. On the other hand, if the thickness of the Si layer is a critical film-thickness or thinner, generation of misfit dislocation can be suppressed. However, the thickness of the Si layer occasionally becomes thinner than a required thickness for device production.

### Experiment 1

Accordingly, the present inventors produced wafers (samples 1 to 3) which were formed with a Si_{1-X}Ge_{X} layer and a strained Si layer on a silicon single crystal wafer using the method described above. For investigating the properties thereof, a relaxation rate of each of the Si_{1-X}Ge_{X} layers were measured by a micro-Raman measurement method. The measurement was performed using RS-3000 manufactured by HORIBA Ltd., an apparatus using a micro-Raman method. Here, a relaxation rate is the amount relatively represented by a degree of lattice relaxation, where the rate is 0% in the case that a lattice constant of the Si_{1-X}Ge_{X} layers is the same with that of Si and the rate is 100% in the case of the inherent lattice constant determined by a Ge concentration. Production conditions of the wafers and measurement results is shown in Table 1. In addition, in each of the samples, the Si_{1-X}Ge_{X} layer was set to be X=0.2, the dose amount of hydrogen ions was set to be 3.0×10¹⁶/cm², a deposition temperature of the Si_{1-X}Ge_{X} layer and the Si layer was set to be 650° C., and relaxing heat-treatment was performed at 900° C. for 7 minutes.

TABLE 1

| | Si Layer/ | | | Relaxation |
|---|---|---|---|---|
| | SiGe Layer | Energy of | Depth of | Rate of |
| | Thickness | Implantation | Implantation | SiGe Layer |
| | (nm) | (KeV) | (nm) | (%) |
| Sample 1 | 20/100 | 12 | 170 | 52.6 |
| Sample 2 | 20/100 | 9.5 | 130 | 57.9 |
| Sample 3 | 20/200 | 16 | 230 | 75.9 |

As shown Table 1, it was found that as a thickness of a Si_{1-X}Ge_{X} layer was thicker, a relaxation rate became higher, or as a position of a hydrogen ion-implanted layer was closer to a Si_{1-X}Ge_{X} layer, a relaxation rate became higher. As described above, as a relaxation rate is higher, larger strain can be introduced to a Si layer to be formed thereon.

On the other hand, while a Si_{1-X}Ge_{X} layer is being deposited as Sample 3, if a Si_{1-X}Ge_{X} layer with a thickness thicker than a critical thickness at the deposition temperature is formed, misfit dislocation is generated and concavity and convexity, called as crosshatch, is generated on a surface thereof. Therefore even if a Si layer is formed thereon, the crosshatch is maintained and causes void defects when, as a bond wafer, the sample is bonded to a base wafer. Therefore, it was found that with regard to a Si_{1-X}Ge_{X} layer to be formed, it is most preferable that the layer is as thick as possible with the critical film-thickness or thinner at a deposition temperature when the layer is deposited on a surface of a silicon single crystal wafer.

### Experiment 2

Next, for investigating the relation of a thickness of a Si layer to which strain is introduced and a strain amount, by the same method with Experiment 1, wafers each having a Si layer with a different thickness were produced. As a bond wafer, each of the wafers was bonded to a base wafer and thereby there was produced SSOI wafers (Samples 4 to 6) as the same manner with the conventional method described above. A strain amount of the strained Si layer was measured by a micro-Raman measurement method. Here, a strain amount is the amount represented by how much a lattice constant of a strained Si layer is expanded or shrank against the lattice constant of Si. In the present specification, in the case of expanding the amount is a positive value. The results are shown in Table 2. In addition, in each of the samples, a thickness of the Si_{1-X}Ge_{X} layer was 100 nm, the dose amount of hydrogen ions was set to be 3.0×10¹⁶/cm², and relaxing heat-treatment was performed at 900° C. for 7 minutes. Moreover, a critical film-thickness at 900° C. of a Si layer in the case of X=0.2 was about 12 nm. Therefore, only with regard to Sample 4, the film thickness of the Si layer was a critical film-thickness at a temperature of relaxing heat-treatment or thicker.

TABLE 2

| | Property of Si Layer | | | |
|---|---|---|---|---|
| | Film- | | | |
| | thickness | Film- | Measurement Results by | |
| | of Si Layer | thickness | Micro-Raman Method | |
| | before | of Strained | Position | |
| | Bonding of | Si Layer | of Raman | Strain |
| | Wafers (nm) | (nm) | Peak(cm⁻¹) | Amount (%) |
| Sample 4 | 22.6 | 16.3 | 517.99 | 0.31 |
| Sample 5 | 9.4 | 5.4 | 516.01 | 0.61 |
| Sample 6 | 5.7 | 1.8 | 513.48 | 0.89 |

In FIG. 2, a thickness of Strained Si layer was a little thinner than a thickness of a Si layer before bonding of the wafers. However, this was caused by etching action and such when a strained Si layer is cleaned before bonding of the wafers. As shown in Table 2, with regard to Sample 4, it is thought that because the thickness of the Si layer has a critical film-thickness or thicker, misfit dislocation was generated and strained amount was reduced. Therefore, it was confirmed that for introducing sufficient strain to a Si layer, it was necessary to make a thickness of a Si layer have a critical film-thickness or thinner, for example, 10 nm or thinner, for suppressing misfit dislocation on the Si/SiGe interface.

However, as described above, if a thickness of Si layer is limited like this, there is caused a problem that degrees of freedom in device designs become smaller and the thickness of the Si layer becomes thinner than a desired thickness.

Accordingly, the present inventors made repeated experiments and found that, even when a thickness of a Si layer is limited as described above, if relaxing heat-treatment is performed to form a strained Si layer by introducing lattice strain in the Si layer and then Si is deposited on a surface thereof, there can be also obtained strain corresponding to relaxation of the Si_{1-X}Ge_{X} layer in the additionally deposited part. In particular, if deposition of Si is performed at 800° C. or less, less than a temperature of relaxing heat-treatment temperature, and furthermore performed at a low temperature of 650° C. or less, the strained Si layer deposited to be increased in a film-thickness can be surely prevented misfit dislocation from being newly generated therein. And thereby, it was found that there can be obtained a strained Si layer which is prevented from dislocation or surface-roughness and has a desired thickness. The present invention was accomplished.

Hereinafter, embodiments of the present invention will be explained with reference to drawings. However, the present invention is not limited thereto.

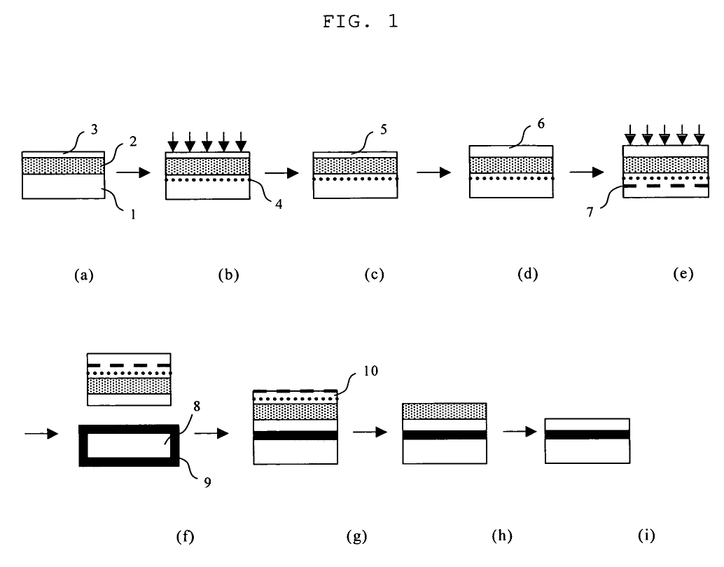

FIG. 1 (a) to (i) is a flow chart showing an example of steps for producing a semiconductor wafer according to the present invention.

First, as FIG. 1 (a), by a vapor growth method and such, a Si_{1-X}Ge_{X} layer 2 and a Si layer 3 are epitaxially-grown in order on a surface of a silicon single crystal wafer 1. Thereby, lattice strain (compression strain) is generated in the Si_{1-X}Ge_{X} layer 2 by the deference to a Si single crystal in a lattice constant. At this time, a thickness of the Si_{1-X}Ge_{X} layer 2 is a critical film-thickness or thinner, in which misfit dislocation is not generated at a deposition temperature of the layer. The critical film thickness of this case is determined by a Ge concentration X and the deposition temperature. However, for example, in the case that a layer of X=0.2 is deposited at 650° C., the thickness is about 100 nm.

On the other hand, a thickness of the Si layer 3 formed on a surface of the Si_{1-X}Ge_{X} layer 2 is a critical film-thickness or thinner, in which misfit dislocation is not generated at a temperature of relaxing heat-treatment to be performed in a later step. The critical film thickness of the Si layer 3 is determined by a Ge concentration X as with the Si_{1-X}Ge_{X} layer 2 and the deposition temperature of the Si layer 3. However, because relaxing heat-treatment at a higher temperature than the deposition temperature of the Si layer 3 is set in a later step, it is necessary that the thickness is a critical film-thickness or thinner, in which misfit dislocation is not generated at the temperature of relaxing heat-treatment performed in a later step. Therefore, the thickness of the Si layer 3 formed on a surface of the Si_{1-X}Ge_{X} layer 2 is determined by a Ge concentration X and a relaxing heat-treatment temperature of the Si_{1-X}Ge_{X} layer 2, for example, in the case that X is set to be X=0.2 and the relaxing heat-treatment is performed at 900° C., the thickness is about 12 nm.

The relation among these critical film-thicknesses, a Ge concentration X, and a heat-treatment temperature can be obtained experimentally.

In addition, as the heat-treatment temperature is higher, a critical film-thickness is lower. Therefore, if the Si_{1-X}Ge_{X} layer 2 deposited with a critical film-thickness or thinner is subjected to relaxing heat-treatment at a higher temperature than the deposition temperature, misfit dislocation is newly generated. However, because the generation of misfit dislocation of this case is near the interface between the surface of the silicon single crystal wafer and the Si_{1-X}Ge_{X} layer 2, the effect thereof to the Si layer 3 can be suppressed.

Moreover, in this case, it is preferable that the thickness of the Si layer is from 3 nm to 10 nm. If so, the thickness of the Si layer is surely a critical film-thickness or thinner, misfit dislocation can be surely prevented from being generated in relaxing heat-treatment to be performed later, and also the thickness becomes so sufficient that the layer is not feared to be removed by etching action in cleaning.

Furthermore, it is preferable that the Si_{1-X}Ge_{X} layer 2 has X≧0.1. And in particular, it is more preferable that the layer has X≧0.2. Thereby, sufficient strain can be introduced to the Si layer in relaxing heat-treatment to be performed later.

In addition, vapor growth can be performed by CVD (Chemical Vapor Deposition) method, MBE (Molecular Beam Epitaxy) method, or the like. In the case of CVD method, for example, as a material gas, a mixed gas of SiH₄ or SiH₂Cl₂ and GeH₄ can be used. As a carrier gas, H₂ can be used. As a growth condition, for example, a temperature may be from 400° C. to 1,000° C. and a pressure may be 100 Torr (1.33×10⁴ Pa) or less.

Next, as shown in FIG. 1 (b), an ion-implanted layer 4 for relaxation is formed inside the silicon single crystal wafer 1 by implanting at least one kind of hydrogen ion, rare gas ion such as argon or helium, and Si ion through the Si layer 3. In the ion-implanted layer 4 for relaxation, bubble, crack, crystal defect and such are formed, lattice relaxation of the Si_{1-X}Ge_{X} layer 2 in the later relaxing heat-treatment is promoted by the presence of them. The amount of ion implantation is preferably 1×10¹⁶ to 4×10¹⁶/cm^{2.} The amount of ion implantation of this case is suppressed to be the extent so as not to cause delamination in the later relaxing heat-treatment. Moreover, because a depth of ion implantation depends on the magnitude of energy of implantation, energy of implantation may be set to be a desired depth of implantation. However, it is more preferable that the ion-implanted layer 4 for relaxation is formed near a surface of the silicon single crystal wafer 1 because relaxation of the Si_{1-X}Ge_{X} layer 2 is more promoted.

Next, as shown in FIG. 1 (c), by performing the relaxing heat-treatment, the Si_{1-X}Ge_{X} layer 2 is lattice-relaxed and a strained Si layer 5 is formed by introducing lattice strain in the Si layer 3. In this time, because the Si layer 3 has a critical film-thickness at a relaxing heat-treatment temperature or thinner, misfit dislocation is not generated in the strained Si layer 5, generation of threading-dislocation can be suppressed, surface-roughness by generation of crosshatch can be suppressed, and a favorable strained Si layer can be formed. Without relaxing strain of the strained Si layer 5 by misfit dislocation, sufficient strain is generated and maintained.

In the case that the Si layer 3 is thin, it is preferable that relaxing heat treatment is performed under an atmosphere of a non-oxidizing gas such as argon, nitrogen, hydrogen, a mixed gas of these, or the like. Moreover, with regard to a temperature and time of heat-treatment, 900° C. or less and 7 minutes or less are preferable for suppressing diffusion of Ge from the Si_{1-X}Ge_{X} layer 2, and 800° C. or more and 7 minutes or more are preferable for providing the Si_{1-X}Ge_{X} layer 2 with sufficient lattice relaxation.

Next, as shown in FIG. 1 (d), a thickness of the strained Si layer 5 is increased by depositing Si on a surface thereof. A thickness of the strained Si layer 6 with a thus increased thickness can be larger than a critical film-thickness at the relaxing heat-treatment, and the thickness can be freely set according to device specifics. In addition, even in an additionally deposited part, there can be obtained strain corresponding to lattice relaxation of the Si_{1-X}Ge_{X} layer 2.

The Si deposition can be also performed by vapor growth such as CVD method, MBE method, or the like. At this time, for not generating misfit dislocation newly and maintaining strain of the strained Si layer, it is preferable that a deposition temperature is 800° C. or less, more preferably, 650° C. or less.

Next, as shown in FIG. 1 (e), an ion-implanted layer 7 for delamination is formed inside the silicon single crystal wafer 1 by implanting at least one kind of hydrogen ion and rare gas ion such as argon or helium through the strained Si layer 6 with the increased thickness. A depth of the ion implantation may be the same with or different from that of the ion-implanted layer 4 for relaxation. The amount of implanted ions is the implantation amount (about 5×10¹⁶/cm²) required for delamination or more. However, in the case that the depth is set to be the same with that of the ion-implanted layer 4 for relaxation, the total amount of implanted ions for relaxation and for delamination may be the required amount of implantation for delamination or more.

Next, as shown FIG. 1 (f), a surface of the strained Si layer 6 of the silicon single crystal wafer 1 as a bond wafer and a surface of a base wafer 8 are closely bonded through a silicon oxide film 9, an insulator film, at a room temperature. As a base wafer 8, there can be used a silicon single crystal wafer or an insulator wafer such as quartz, silicon carbide, alumina, diamond or the like. In the case of an insulator wafer, they may be directly bonded not through an insulator film. In this case, before they are bonded at a room temperature, it is usually necessary to clean sufficiently the surfaces to be bonded. Therefore, for example, cleaning with a mixed aqueous solution of NH₄OH and H₂O (SC-1: Standard Cleaning 1), which is subjected to a general Si wafer, is performed. However, in the present invention, because the Si_{1-X}Ge_{X} layer is not exposed on the most surficial before bonding of the wafer, if such cleaning being subjected to such a general Si wafer is performed, a surface thereof is not roughened. In addition, in FIG. 1 (f), the case is shown that a silicon oxide film 9 is formed on a surface of a base wafer 8. However, the film may be formed on either of a surface of the strained Si layer 6 or a surface of the base wafer 8, or on both of them.

Next, as shown FIG. 1 (g), delamination is performed by the ion-implanted layer 7 for delamination. In this case, for example, by adding heat treatment (delaminating heat-treatment) at about 400° C. to 600° C., delamination can be performed so that the ion-implanted layer 7 for delamination becomes cleaved surface. Thereby, the Si_{1-X}Ge_{X} layer 2 and a Si layer 10 that is one part of the silicon single crystal wafer 1 is transferred to the side of the base wafer, and thereby the silicon layer 10 becomes the most surficial layer.

In addition, as a pretreatment of the step of closely bonding the surface of the strained Si layer 6 and the surface of the base wafer 8 as shown in FIG. 1 (f), if strength of the closely bonding is enhanced by subjecting the surfaces provided for the closely bonding to plasma treatment, delamination can be mechanically performed at the ion-implanted layer 7 for delamination without delaminating heat-treatment after closely bonding.

Next, as shown in FIG. 1 (h) and (i), the strained Si layer 6 is exposed by removing the most surficial Si layer 10 and the Si_{1-X}Ge_{X} layer 2 transferred to the base wafer side.

It is preferable that the removing is performed by at least any one of polishing, etching, and removing an oxide film after thermal oxidation at the temperature of 80° C. or less under an oxidizing atmosphere because a surface of the strained Si layer 6 to be finally exposed can be flat and smooth. In particular, polishing is preferable because the Si layer 10 and the Si_{1-X}Ge_{X} layer 2 can be removed as surface-roughness that is generated in the delamination and that remains on the surface of the Si layer 10 is being improved. For this polishing, for example, a conventional CMP can be used.

Moreover, in the case of etching, a mixed aqueous solution of NH₄OH and NH₄NO₃, TMAH (tetramethylammonium hydroxide), or an aqueous solution of NH₄OH can be used for the Si layer 10 as an etching solution. According to these etching solution, when the Si layer 10 is removed and the etching solution reaches the Si_{1-X}Ge_{X} layer 2, the etching stops by the selectivity of the etching solution, namely etch stop happens. Moreover, a mixed aqueous solution of HF and H₂O₂ and CH₃COOH, a mixed aqueous solution of NH₄OH and H₂O₂, or a mixed aqueous solution of HF and HNO₃ can be used for the Si_{1-X}Ge_{X} layer 2 as an etching solution. In this case, when the etching solution reaches the strained Si layer 6, etch stop happens. The etch stop method as described above is preferable because the Si layer 10 and the Si_{1-X}Ge_{X} layer 2 can be completely removed and the surface of the strained Si layer 6 to be exposed becomes flat and smooth.

Moreover, thermal oxidation at 800° C. or less and removal of an oxide film thereafter are preferable because misfit dislocation is not surely generated since the treatments are heat treatments at a low temperature. The thermal oxidation can be performed under an oxidizing atmosphere, for example, under a 100% wet oxygen atmosphere. Moreover, the removal of an oxide film can be performed, for example, by immersing a wafer in a 15% HF aqueous solution. If removing steps of these different methods are combined appropriately, the surface of the strained Si layer can be more flat and smooth.

In addition, in an embodiment shown in FIG. 1, after increasing a thickness of the strained Si layer, formation of an ion-implanted layer for delamination and such are performed. However, steps can be also performed that, after the strained Si layer is formed as shown in FIG. 1 (c), by the same method with FIG. 1 (e) to (i), an ion-implanted layer for delamination is formed inside a silicon single crystal wafer, a surface of the strained Si layer of the silicon single crystal wafer as a bond wafer and a surface of a base wafer are closely bonded directly or through an insulator film, thereafter delamination is performed at the ion-implanted layer for delamination, the strained Si layer with a critical film-thickness at a temperature of later relaxing heat-treatment or thinner is exposed by removing the most surficial Si layer and the Si_{1-X}Ge_{X} layer transferred to the side of the base wafer by the delamination, thereafter Si is deposited on the strained Si layer 6, and thereby a thickness of the strained Si layer is increased.

By these steps, there can be produced a SSOI wafer formed with a strained Si layer having a desired thickness in which dislocation and surface-roughness can be prevented and the thickness can apply to device designs of various specifics.

### EXAMPLES

Hereinafter, examples and comparative examples according to the present invention will be explained concretely. However, the present invention is not limited thereto. (Example 1, 2, Comparative Example 1, 2) According to the steps shown in FIG. 1, SSOI wafers were produced (Example 1, 2). Moreover, SSOI wafers were produced according to the steps as shown in FIG. 1 except for not performing a step of increasing a thickness of the strained Si layer (Comparative Example 1, 2). And, strain amounts of the strained Si layers of these SSOI wafers were measured. In addition, the measurements of the strain amounts were performed by using RS-3000 manufactured by HORIBA, Ltd., an apparatus using a micro-Raman method. Moreover, in Examples 1, 2, and Comparative Example 1, a thickness of the Si layer formed on the Si_{1-X}Ge_{X} layer is set to be 10 nm, a critical film-thickness at a temperature of the relaxing heat-treatment (900° C.) or thinner, and in Comparative Example 2, 25 nm, the critical film-thickness or thicker. The other production condition and the measurement results of the strain amounts are shown in Table 3.

TABLE 3

| | | | Comparative | Comparative |
|---|---|---|---|---|
| | Example 1 | Example 2 | Example 1 | Example 2 |
| Silicon Single Crystal Wafer | Diameter: 300 mm, Plane Orientation: (100), Conductivity Type: p-Type, Resistivity: 10Ω · cm | | | |
| Deposition of SiGe layer | Temperature: 650° C., Film-thickness: 100 nm, Ge Concentration: 20% (X = 0.2) | | | |
| Deposition of Si layer | Temperature: 650° C., Film-thickness: 10 nm | | | Temperature: 650° C., |
| | (Critical Film-thickness or Thinner), | | | Film-thickness: 25 nm |
| | | | | (Critical Film- |
| | | | | thickness or thicker), |
| Formation of Ion-implanted | Implanted ion: H⁺ Ion, Implantation Amount: 3 × 10¹⁶/cm², | | | |
| Layer for Relaxation | Implantation Energy: 9.5 keV (Implantation Depth: 120 nm from Surface of Si layer) | | | |
| Relaxing Heat-treatment | Temperature: 900° C., Treatment Time: 7 Minutes, Atmosphere: 100% Hydrogen | | | |
| Increasing of Thickness | Temperature: 650° C., | Temperature: 650° C., | none | none |
| of Strained Si Layer | Increased Thickness: 10 nm | Increased Thickness: 40 nm | | |
| Formation of Ion-implanted | Implanted ion: H⁺Ion, Implantation Amount: 5.5 × 10¹⁶/cm², | | | |
| Layer for Delamination | Implantation Energy: 26 keV | | | |
| | (Implantation Depth: 310 nm from Surface of Strained Si layer) | | | |
| Bonding to Base Wafer | Closely Bonding to Base Wafer (Diameter: 300 mm, | | | |
| | Plane Orientation: (100), Conductivity Type: p-Type, | | | |
| | Resistivity: 10Ω · cm, | | | |
| | Thickness: 400 nm, Having Oxide Film)at Room Temperature | | | |
| Heat-treatment for Delamination | Temperature: 500° C., Treatment Time: 30 Minutes, | | | |
| | Atmosphere: Nitrogen | | | |
| Etching of Most Surficial | Etching Solution: NH₄OH:NH₄NO₃ = 200 ml:1 g Aqueous Solution (Using 29 wt % NH₄OH Aqueous Solution), | | | |
| Si Layer | Etching Temperature: 21° C. | | | |
| Etching of SiGe Layer | Etching Solution: HF:H₂O₂:CH₃COOH = 1:2:3 Aqueous Solution (Using 50 wt % HF Aqueous Solution, | | | |
| | 30 wt % H₂O₂ Aqueous Solution, 99 Wt % CH₃COOH Aqueous Solution,), | | | |
| | Etching Temperature: 21° C. | | | |
| Thickness of | 13.8 nm | 41.2 nm | 5.4 nm | 16.3 nm |
| Strained Si Layer | | | | |
| Strain Amount | 0.53% | 0.49% | 0.61% | 0.31% |

As shown in Table 3, it was confirmed that the strained Si layers of SSOI wafers of Example 1 and 2 had sufficient thickness with a critical film-thickness at a temperature of relaxing heat-treatment (900° C.) or thicker and furthermore had the equivalent level of a strain amount to that of a SSOI wafer of Comparative Example 1 having a strained Si layer with a critical film-thickness or thinner. Moreover, with regard to the SSOI wafer of Comparative Example 2, misfit dislocation is generated in the strained Si layer and the strain amount thereof is reduced because the Si layer with a critical film-thickness at a temperature of relaxing heat-treatment or thicker is formed on the Si_{1-X}Ge_{X} layer.

In addition, a final thickness of the strained Si layer is slightly thinner than the total film-thickness of the Si layer to be deposited. However, this was caused by etching action when the strained Si layer was cleaned by SC-1 cleaning before the wafers were bonded, and caused by over-etching when the Si_{1-X}Ge_{X} layer was removed by etching.

### EXAMPLE 3

Si was deposited on a surface of the strained Si layer of the SSOI wafer of Comparative Example 1 and a thickness of the strained Si layer was increased only by 20 nm. In addition, the deposition temperature of this case was 650° C. The strain amount of the strained Si layer was measured again. The strain amount was 0.52% and it was confirmed that the strain amount was a sufficient amount of the equivalent level to that of Examples 1, 2. And also, a thickness of the strained Si layer became 22.5 nm, a sufficient thickness.

In addition, the present invention is not limited to the embodiments described above. The above-described embodiments are mere examples and those having substantially the same constitution as technical ideas described in the claims of the present invention and providing the similar functions and advantages are included in the scope of the present invention.

What is claimed is:

1. A method for producing a semiconductor wafer comprising at least steps of, forming a Si_{1-X}Ge_{X} layer (0<X<1) with a critical film-thickness at a deposition temperature of the layer or thinner on a surface of a silicon single crystal wafer and then forming a Si layer with a critical film-thickness at a temperature of later relaxing heat-treatment or thinner thereon, forming an ion-implanted layer for relaxation inside the silicon single crystal wafer by implanting at least one kind of hydrogen ion, rare gas ion, and Si ion through the Si layer, thereafter performing the relaxing heat-treatment, thereby to make the Si_{1-X}Ge_{X} layer lattice-relaxed and to form a strained Si layer by introducing lattice strain in the Si layer, thereafter depositing Si on a surface of the strained Si layer, and thereby to increase a thickness of the strained Si layer.

2. The method for producing a semiconductor wafer according to claim 1, wherein an ion-implanted layer for delamination is formed inside the silicon single crystal wafer by implanting at least one kind of hydrogen ion and rare gas ion through the strained Si layer with the increased thickness, a surface of the strained Si layer with the increased thickness of the silicon single crystal wafer as a bond wafer and a surface of a base wafer are closely bonded directly or through an insulator film, thereafter delamination is performed at the ion-implanted layer for delamination, and the strained Si layer is exposed by removing the most surficial Si layer and the Si_{1-X}Ge_{X} layer transferred to the side of the base wafer by the delamination.

3. A method for producing a semiconductor wafer comprising at least steps of, forming a Si_{1-X}Ge_{X} layer (0<X<1) with a critical film-thickness at a deposition temperature of the layer or thinner on a surface of a silicon single crystal wafer and then forming a Si layer with a critical film-thickness at a temperature of later relaxing heat-treatment or thinner thereon, forming an ion-implanted layer for relaxation inside the silicon single crystal wafer by implanting at least one kind of hydrogen ion, rare gas ion, and Si ion through the Si layer, thereafter performing the relaxing heat-treatment, thereby to make the Si_{1-X}Ge_{X} layer lattice-relaxed and to form a strained Si layer by introducing lattice strain in the Si layer, thereafter forming an ion-implanted layer for delamination inside the silicon single crystal wafer by implanting at least one kind of hydrogen ion and rare gas ion through the strained Si layer, closely bonding a surface of the strained Si layer of the silicon single crystal wafer as a bond wafer and a surface of a base wafer directly or through an insulator film, thereafter performing delamination at the ion-implanted layer for delamination, exposing the strained Si layer by removing the most surficial Si layer and the Si_{1-X}Ge_{X} layer transferred to the side of the base wafer by the delamination, and thereafter depositing Si on a surface of the strained Si layer, and thereby to increase a thickness of the strained Si layer.

4. The method for producing a semiconductor wafer according to claim 1, wherein the step of depositing Si on a surface of the strained Si layer is performed at 800° C. or less.

5. The method for producing a semiconductor wafer according to claim 2, wherein the step of depositing Si on a surface of the strained Si layer is performed at 800° C. or less.

6. The method for producing a semiconductor wafer according to claim 3, wherein the step of depositing Si on a surface of the strained Si layer is performed at 800° C. or less.

7. The method for producing a semiconductor wafer according to claim 1, wherein the Si_{1-X}Ge_{X} layer has X≧0.1.

8. The method for producing a semiconductor wafer according to claim 2, wherein the Si_{1-X}Ge_{X} layer has X≧0.1.

9. The method for producing a semiconductor wafer according to claim 3, wherein the Si_{1-X}Ge_{X} layer has X≧0.1.

10. The method for producing a semiconductor wafer according to claim 4, wherein the Si_{1-X}Ge_{X} layer has X≧0.1.

11. The method for producing a semiconductor wafer according to claim 5, wherein the Si_{1-X}Ge_{X} layer has X≧0.1.

12. The method for producing a semiconductor wafer according to claim 6, wherein the Si_{1-X}Ge_{X} layer has X≧0.1.

13. The method for producing a semiconductor wafer according to claim 1, wherein the thickness of the Si layer with the critical film-thickness or thinner to be formed is from 3 nm to 10 nm.

14. The method for producing a semiconductor wafer according to claim 2, wherein the thickness of the Si layer with the critical film-thickness or thinner to be formed is from 3 nm to 10 nm.

15. The method for producing a semiconductor wafer according to claim 3, wherein the thickness of the Si layer with the critical film-thickness or thinner to be formed is from 3 nm to 10 nm.

16. The method for producing a semiconductor wafer according to claim 1, wherein the removing of the most surficial Si layer and/or the Si_{1-X}Ge_{X} layer is performed by at least any one of polishing, etching, and removing an oxide film after thermal oxidation at the temperature of 800° C. or less under an oxidizing atmosphere.

17. The method for producing a semiconductor wafer according to claim 2, wherein the removing of the most surficial Si layer and/or the Si_{1-X}Ge_{X} layer is performed by at least any one of polishing, etching, and removing an oxide film after thermal oxidation at the temperature of 800° C. or less under an oxidizing atmosphere.

18. The method for producing a semiconductor wafer according to claim 3, wherein the removing of the most surficial Si layer and/or the Si_{1-X}Ge_{X} layer is performed by at least any one of polishing, etching, and removing an oxide film after thermal oxidation at the temperature of 800° C. or less under an oxidizing atmosphere.

19. The method for producing a semiconductor wafer according to claim 1, wherein a silicon single crystal wafer or an insulator wafer is used as the base wafer.

20. The method for producing a semiconductor wafer according to claim 2, wherein a silicon single crystal wafer or an insulator wafer is used as the base wafer.

21. The method for producing a semiconductor wafer according to claim 3, wherein a silicon single crystal wafer or an insulator wafer is used as the base wafer.

22. The method for producing a semiconductor wafer according to claim 1, wherein the temperature of the relaxing heat-treatment is 900° C. or less.

23. The method for producing a semiconductor wafer according to claim 2, wherein the temperature of the relaxing heat-treatment is 900° C. or less.

24. The method for producing a semiconductor wafer according to claim 3, wherein the temperature of the relaxing heat-treatment is 900° C. or less.
